(19) United States
(12) Patent Application Publication
(10) Pub. No.: US 2024/0380179 A1
(43) Pub. Date: Nov. 14, 2024

(54) LASER APPARATUS

(71) Applicant: TRUMPF Photonic Components GmbH, Ulm (DE)

(72) Inventors: Holger Joachim Moench, Vaals (NL); Stephan Gronenborn, Aachen (DE)

(21) Appl. No.: 18/780,554

(22) Filed: Jul. 23, 2024

Related U.S. Application Data
(63) Continuation of application No. PCT/EP2023/051357, filed on Jan. 20, 2023.

(30) Foreign Application Priority Data
Jan. 25, 2022 (DE) 10 2022 101 668.4

(51) Int. Cl. H01S 5/183

(52) U.S. Cl. CPC H01S 5/18386

(57) ABSTRACT

A laser apparatus includes a vertical-emitting semiconductor laser device for emitting laser light. The vertical-emitting semiconductor laser device includes a main body having a first mirror section, a second mirror section, and an active layer arranged between the first mirror section and the second mirror section for generating the laser light. The main body has an emission region on a surface thereof for emission of the laser light. The laser apparatus further includes an optical meta-element arranged on the emission region. The optical meta-element includes an optical metamaterial for shaping the laser light. The optical meta-element is configured to emit the laser light in at least one laser mode.

### CROSS REFERENCE TO RELATED APPLICATIONS

This application is a continuation of International Application No. PCT/EP2023/051357 (WO 2023/144033 A1), filed on Jan. 20, 2023, and claims benefit to German Patent Application No. DE 10 2022 101 668.4, filed on Jan. 25, 2022. The aforementioned applications are hereby incorporated by reference herein.

### FIELD

Embodiments of the present invention relate to a laser apparatus comprising a vertical-emitting semiconductor laser device for emitting laser light.

### BACKGROUND

A metamaterial is an artificially produced structure, the transmissivity of which for electrical and magnetic fields (permittivity and permeability) deviates from that which is common in nature. This is accomplished by specifically manufactured, typically periodic, microscopically fine structures (cells, individual elements) of electrically or magnetically effective materials in their interiors. If light is transmitted through such a meta-surface consisting of metamaterial, the individual light waves are retarded at these elements to different extents. For this reason, the choice of the structure of the meta-element can be used to design an optically effective layer thickness. Behind the meta-surface, the light waves then superpose to form new wavefronts with different propagation directions. Especially in the case of meta-lenses, these elements are designed and distributed such that downstream thereof, the light converges to a focal point-as in the case of a conventional lens. Generally, however, meta-surfaces can also be designed in such a way that they imitate the functionalities of other optical components, such as of beam splitters, polarizers or diffraction gratings. This forms the basis for the meta-element.

The laser light forms at least one laser mode in a cavity that is formed by the mirror sections. The semiconductor laser device can be what is known as a VCSEL (vertical-cavity surface-emitting laser). The meta-element can have meta-structures of different dimensions in this sub-wavelength range with respect to the laser light.

The reflection of the laser light to be coupled out of the main body of the semiconductor laser device at the surface can be set by way of the meta-element. Here, the reflection can be set such that specific laser modes are stabilized at a lower energy introduced into the laser apparatus. Accordingly, the coupled-out laser light has the intensity profile of the stabilized laser mode.

### SUMMARY

Embodiments of the present invention provide a laser apparatus. The laser apparatus includes a vertical-emitting semiconductor laser device for emitting laser light. The vertical-emitting semiconductor laser device includes a main body having a first mirror section, a second mirror section, and an active layer arranged between the first mirror section and the second mirror section for generating the laser light. The main body has an emission region on a surface thereof for emission of the laser light. The laser apparatus further includes an optical meta-element arranged on the emission region. The optical meta-element includes an optical metamaterial for shaping the laser light. The optical meta-element is configured to emit the laser light in at least one laser mode.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a VCSEL with a meta-element on the emission region according to some embodiments.

### DETAILED DESCRIPTION

Embodiments of the present invention provide a laser apparatus with a vertical-emitting semiconductor laser device for emitting laser light comprising a main body having a first mirror section, a second mirror section, and an active layer for generating the laser light, which is arranged between the two mirror sections, wherein the main body has on its surface an emission region which is provided for the emission of the laser light and on which an optical meta-element is arranged, which is provided for shaping the laser light, wherein the meta-element is designed to emit the laser light in the case of at least one laser mode.

In an advantageous development, the meta-element is formed as a meta-layer on the emission region with a layer thickness that varies along the surface. As a result of this, the effective reflectivity of the meta-element can be varied locally along the surface such that first sites on the surface are formed at which the meta-element reflects the laser light more strongly back into the cavity than at second sites. The sites can also be specified by two different angles.

The layer thickness is advantageously varied according to at least one laser mode of the laser light forming in the semiconductor laser device. Here, the layer thickness can be varied in dependence on a density of the meta-structure, with the result that, for example, the layer thickness is lower at sites of high density of the meta-structures than at sites of lesser density of the meta-structures. In this way, a reflection of the laser light which is influenced by the density of the meta-structures can be set by way of the layer thickness. The layer thickness can be understood to be an effective layer thickness, which is achieved by varying the density of the meta-structures. The physical layer thickness (e.g. tower height) can preferably be constant. If the density/size of the towers is varied, the result is a correspondingly varying refractive index and a correspondingly varying optical path length.

Alternatively or additionally, the density of the meta-structures can differ in different directions along the surface. For example, with reference to the surface area, there can be a first density in a first direction and a second density in a second direction.

A particular development involves the metamaterial having meta-extensions as meta-structures, which extend from a base section approximately parallel in the same direction. The meta-extensions can be formed in the manner of towers. The height of the individual meta-extensions can vary. The base section is a continuous film formed in one piece with the meta-extensions. Meta-extensions can also be understood to be grooves, ribs, irregular structures characterized by a variation in the height with respect to a surface normal of the surface of the main body, bumps, depressions such as dents, webs, pyramids and/or other structures that lead to a retardation of the wavefronts of the laser light propagating through the meta-element.

The density of the meta-extensions preferably varies along the surface. Here, the local density of the meta-extensions can be set according to an intended shape of the laser light.

Additionally or alternatively, the density of the meta-extensions can vary according to at least one laser mode of the laser light forming in the semiconductor laser device. The local density of the meta-extensions can hereby be set according to the shape and the laser mode.

In an advantageous development, the meta-extensions can be formed by oxidation and/or by etching of the material of the meta-element. The metamaterial between the meta-extensions and the base section can here be removed completely by etching and in particular be filled with a replacement material having a refractive index which differs from the metamaterial. During oxidation of the metamaterial between the meta-extensions and the base section, the refractive index of the metamaterial can be changed. For example, the interposed metamaterial can be converted into silicon dioxide.

In particular, the layer thickness and/or the density of the meta-extensions can be varied in such a way that a high reflectivity is present between the main body and the meta-element at sites along the surface at which there is a high light intensity of the laser mode.

It is advantageous to stack a first meta-layer and a second meta-layer on top of each other. Here, a first meta-layer can be arranged on the surface of the main body and serve as a reflection layer, and the second meta-layer can serve to shape the laser light. In this way, a functional separation between the reflection setting and the shaping of the laser light is achieved.

It is furthermore advantageous to stack different films one on top of the other, wherein some of the films can have meta-structures, while others have no meta-structures. Contiguous films may consist of material that is transmissive to the laser light. A film of silicon dioxide may be arranged between the first meta-layer and the second meta-layer. The film of silicon dioxide is preferably not structured. The first meta-layer can have a layer thickness of less than a quarter of the wavelength of the laser light. The second meta-layer can have a layer thickness of approximately a quarter of the wavelength of the laser light.

The meta-element is preferably made from a silicon-containing material. Furthermore, the meta-element can be applied to the semiconductor laser device before or after structuring. Non-structured layers are preferably deposited on the laser wafer, for example, by way of PECVD. The structuring is then lithographically applied to the semiconductor. Alternatively, the optical meta-structure can be produced separately in other materials (glass, dielectrics, silicon). This wafer can then be bonded to the laser wafer using a bonding method.

One development may involve the meta-element shaping the laser light in dependence on the polarization. Here, the meta-element can bring about different shapes of the laser light for different polarization directions. In particular, this can be achieved if the meta-extensions are formed with an elliptical cross section which is aligned parallel to the surface. Alternatively or additionally, the cross section can also be asymmetric.

Embodiments of the present invention will be explained in more detail below with reference to the associated drawing. Direction indications in the following explanation are to be understood according to the reading direction of the drawing.

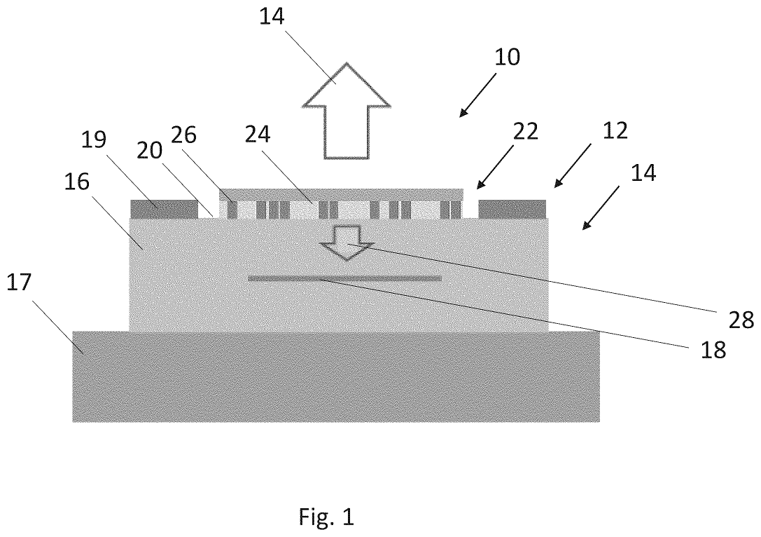

FIG. 1 shows a laser apparatus 10, which comprises a vertical-emitting semiconductor laser device 12, which is provided for emitting laser light 14. The semiconductor device 12 is what is known as a VCSEL (vertical-cavity surface-emitting laser).

The semiconductor device 12 comprises a main body 16, which has a first mirror section, a second mirror section, and an active layer 18 for generating the laser light 14 arranged between the two mirror sections. The laser light 14 forms at least one laser mode in a cavity positioned between the mirror sections.

The main body 16 is arranged on a substrate 17. On an opposite side of the main body 16, electrical contacts 19 are arranged, which are provided for introducing electrical energy. The semiconductor laser device 12 is constructed in the manner of a stack.

An emission region 22 from which the laser light 14 is emitted is formed on the surface 20 of the main body 16. Arranged on the emission region 22 is an optical meta-element 24 provided for shaping the laser light 14. Here, the meta-element 24 acts like a refractive lens, a diffractive diffraction structure, a diffuser, a beam splitter, a beam deflector, and/or a hologram.

The meta-clement 24 has meta-structures of different dimensions in the sub-wavelength range with respect to the laser light 14. The meta-structures can be formed by tower-type or rod-type optically active meta-extensions 26, which project perpendicularly from a base section. The meta-extensions 26 form in particular a brush-type structure. It is also possible to use alternative, other meta-structures which cause retardation of the laser light. The height of the individual meta-extensions 26 with respect to the base section can vary. The base section is a contiguous film that is formed in one piece with the meta-extensions 26. The base section can be arranged on the surface 20.

The reflection 28 of the laser light that is to be coupled out of the main body 16 of the semiconductor laser device 12 at the surface 20 is set by way of the meta-element 24. The reflection 28 can here be set such that specific laser modes are stabilized at a lower energy introduced into the laser apparatus 10. Accordingly, the coupled-out laser light 14 has the intensity profile of the stabilized laser mode. By forming the meta-element 24 in dependence on the laser mode, a laser mode selection in which only specific laser modes are stabilized can be carried out.

The meta-element 24 is formed as a meta-layer on the emission region 22 with a layer thickness which varies along the surface 20. The optically effective layer thickness is critical for the optical properties and the shaping of the laser light. The effective layer thickness can differ from the physical layer thickness, since the effective layer thickness is influenced by the meta-structures. As a result, the effective reflectivity of the meta-element 24 can be varied locally along the surface 20. The variation of the layer thickness can be adapted to the laser modes of the laser light 14 in such a way that the reflectivity is greater at regions of the surface at which the laser mode has a maximum light intensity. The effective layer thickness can here differ by a quarter of the wavelength, with the result that no destructively acting phase shift occurs.

If the density or the cross section of the meta-extensions are changed locally, the effective refractive index at this site changes. The physical layer thickness can remain the same. The anti-reflective property for a wavelength can therefore be present only at the sites with a specific fill factor and it will be more and more out of phase at the other ones with a deviating fill factor.

The density of the meta-extensions 26 varies locally along the surface 20 according to the intended shaping of the laser light 14. Furthermore, the layer thickness can be varied in dependence on a density of the meta-extensions 26 with reference to the surface area, with the result that the layer thickness is lower at sites at which there is a higher density of the meta-extensions 26 than at sites of lower density of the meta-extensions 26. The density of the meta-extensions 26 can vary in accordance with at least one laser mode of the laser light 14 forming in the semiconductor laser device 12. The meta-extensions 26 can be formed by oxidation and/or by etching of the material of the meta-element 24.

The meta-extensions 26 can have a round, preferably circular, cross section which is oriented parallel to the surface 20.

The meta-element 24 can be achieved by coating the emission region 22 of a top or bottom emitter with an at least partially transparent layer, which preferably comprises silicon. The layer thickness can be chosen here such that a path difference of a quarter of the wavelength is achieved when the laser light passes through the layer. The layer can be laterally selectively changed, for example removed by way of etching or locally changed in a chemical manner (for example by way of local oxidation). The structures for the meta-extensions 26 can be formed by way of a UV lithography mask. Next, etching and/or oxidation of the material between the meta-extensions 26 can take place. Finally, the meta-element 24 can be coated with a transparent capping layer 30.

Alternatively, the surface can be coated with a PECVD or atomic layer deposition coating. Next, silicon nitride having a thickness of a quarter of the wavelength can be applied. The structures for the meta-extensions 26 can be formed by way of a UV lithography mask in connection with selective etching of the silicon dioxide and the silicon nitride.

As a further alternative, meta-extensions 26 could be etched directly into the material of the main body 16, that is to say for example into gallium arsenide. Next, a layer of silicon nitride, silicon dioxide, an atomic layer deposition coating, a polymer, or another encapsulation can be applied.

In an embodiment which is not shown in FIG. 1, a first meta-layer can be arranged on a second meta-layer. In this case, a first meta-layer can be arranged on the surface 20 of the main body 16 and act as a reflection layer. The second meta-layer can serve to shape the laser light in connection with the first meta-layer. To ensure that the two meta-layers are separated from each other, a film made of a different material, for example silicon dioxide, can be arranged between the first meta-layer and the second meta-layer. The film of silicon dioxide, for example, is preferably not structured. Structuring methods (etching, oxidation) which are applied to the meta-layers do not substantially attack the intermediate film. The first meta-layer can have a layer thickness of less than a quarter of the wavelength of the laser light 14. The second meta-layer can have a layer thickness of approximately a quarter of the wavelength of the laser light 14.

One development can involve the meta-element 24 shaping the laser light 14 in dependence on the polarization. The meta-element 24 can here bring about different shapes of the laser light 14 for different polarization directions. For this purpose, the meta-extensions 26 can be formed with an elliptical cross section which is oriented parallel to the surface 20.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A laser apparatus comprising:
a vertical-emitting semiconductor laser device for emitting laser light, the vertical-emitting semiconductor laser device comprising a main body having a first mirror section, a second mirror section, and an active layer arranged between the first mirror section and the second mirror section for generating the laser light, wherein the main body has an emission region on a surface thereof for emission of the laser light, and
an optical meta-element arranged on the emission region, the optical meta-element comprising an optical metamaterial for shaping the laser light, wherein the optical meta-element is configured to emit the laser light in at least one laser mode.

2. The laser apparatus as claimed in claim 1, further comprising a reflection layer arranged between the emission region and the optical meta-element.

3. The laser apparatus as claimed in claim 1, wherein the optical meta-element is formed as a meta-layer on the emission region, wherein an optically effective layer thickness of the meta-layer varies along the surface.

4. The laser apparatus as claimed in claim 3, wherein the layer thickness varies according to the at least one laser mode of the laser light forming in the semiconductor laser device.

5. The laser apparatus as claimed in claim 1, wherein the optical metamaterial has meta-extensions that extend from a base section approximately parallel in a same direction.

6. The laser apparatus as claimed in claim 5, wherein a density of the meta-extensions varies along the surface.

7. The laser apparatus as claimed in claim 6, wherein the density of the meta-extensions varies according to the at least one laser mode of the laser light forming in the semiconductor laser device.

8. The laser apparatus as claimed in claim 6, wherein the density of the meta-extensions is due to oxidation and/or etching of the optical metamaterial of the optical meta-element.

9. The laser apparatus as claimed in claim 6, wherein a layer thickness of the optical meta-element and/or the density of the meta-extensions varies in such a way that a high reflectivity is present between the main body and the optical meta-element at sites along the surface at which there is a high light intensity of the at least one laser mode.

10. The laser apparatus as claimed in claim 1, wherein the optical meta-element comprises a first meta-layer and a second meta-layer stacked one another and arranged on the emission region.

11. The laser apparatus as claimed in claim 9, wherein the optical meta-element further comprises a film comprising a material of at least one of the first meta-layer and the second meta-layer, the film being arranged between the first meta-layer and the second meta-layer.

12. The laser apparatus as claimed in claim 1, wherein the optical meta-element comprises a silicon-containing material.

13. The laser apparatus as claimed in claim 1, wherein the optical meta-element shapes the laser light in dependence on a polarization.

14. The laser apparatus as claimed in claim 13, wherein the optical meta-element has meta-extensions having an asymmetric or elliptical cross section, which is oriented parallel to the surface.
